(19) United States
(12) Patent Application Publication
(10) Pub. No.: US 2013/0092457 A1
(43) Pub. Date: Apr. 18, 2013

(54) SOLAR POWER IN A VEHICLE

(71) Applicant: Reinhard Wecker, Irvine, CA (US)

(72) Inventors: Reinhard Wecker, Irvine, CA (US); Kevin Walsh, Orange, CA (US)

(73) Assignee: FISKER AUTOMOTIVE, INC., Irvine, CA (US)

(21) Appl. No.: 13/144,690

(22) PCT Filed: Jan. 15, 2010
(86) PCT No.: PCT/US2010/021188

§ 371 Date: Feb. 29, 2012

Related U.S. Application Data
(60) Provisional application No. 61/144,976, filed on Jan. 15, 2009.

(51) Int. Cl. B60K 16/00; H01L 31/048; H01L 31/05

(52) U.S. Cl. CPC B60K 16/00; H01L 31/05; H01L 31/048
USPC 180/2.2; 136/244; 136/251

(57) ABSTRACT

A photovoltaic apparatus for a vehicle including a plurality of solar modules electrically isolated from each other and adapted to receive solar radiation and convert the radiation to electrical energy. The apparatus includes at least one DC/DC converter electrically coupled to the electrically isolated modules adapted to receive the electrical energy from the solar modules and boost the voltage to be delivered to at least one component of the vehicle. The solar modules include a plurality of solar cells adapted to receive solar radiation and convert the radiation to electrical energy.

### BACKGROUND

The present disclosure relates generally to a vehicle, and more particularly to a vehicle that utilizes solar power as an energy source.

### DESCRIPTION OF THE RELATED ART

Vehicles, such as a motor vehicle, utilize an energy source in order to provide power to operate a vehicle. While petroleum based products dominate as an energy source, alternative energy sources are available, such as methanol, ethanol, natural gas, hydrogen, electricity, solar or the like. A hybrid powered vehicle utilizes a combination of energy sources in order to power the vehicle. Such vehicles are desirable since they take advantage of the benefits of multiple fuel sources, in order to enhance performance and range characteristics of the vehicle, as well as reduce environmental impact relative to a comparable gasoline powered vehicle.

An example of a hybrid vehicle is a vehicle that utilizes both electric and solar energy as power sources. An electric vehicle is environmentally advantageous due to its low emissions characteristics and general availability of electricity as a power source. However, battery storage capacity limits the performance of the electric vehicle relative to a comparable gasoline powered vehicle. Solar energy is readily available, but may not be sufficient by itself to operate the vehicle. Thus, there is a need in the art for a hybrid vehicle with an improved photovoltaic energy distribution system.

### SUMMARY

Accordingly, the present disclosure relates to a photovoltaic apparatus for a vehicle including a plurality of solar modules electrically isolated from each other and adapted to receive solar radiation and convert the solar radiation to electrical energy. At least one DC/DC converter is electrically coupled to the electrically isolated modules and is adapted to receive the electrical energy from the solar modules and boost the voltage to be delivered to at least one component associated with the vehicle.

The present disclosure further provides for a vehicle having a photovoltaic apparatus including a vehicle body with an outer surface, a plurality of solar modules are mounted on the outer surface of the vehicle. The solar modules are electrically isolated from each other and adapted to receive solar radiation and convert the radiation to electrical energy. At least one DC/DC converter is electrically coupled to the electrically isolated modules and is adapted to receive the electrical energy from the solar modules and boost the voltage to be delivered to at least one component of the vehicle.

The present disclosure further provides for a method of delivering electrical energy to a vehicle from a photovoltaic apparatus. The method includes the steps of collecting solar radiation energy on a plurality of electrically isolated solar modules. Each solar module is adapted to receive solar radiation and convert the received radiation into electrical energy, The collected electrical energy converted from solar energy is delivered to at least one DC/DC converter. The converter boosts the electrical energy, and outputs the boosted electrical energy from the converter to the vehicle.

An advantage of the present disclosure is that the solar panel covers a large surface area of the vehicle. Still another advantage of the present disclosure is that the solar panel is curvilinear in shape. Yet another advantage of the present disclosure is that the solar panel includes an integral graphics pattern. Still yet another advantage of the present disclosure is that the solar panel is split into independent modules to maximize efficiency at different solar radiation angles and partial shading conditions with MPP tracking. A further advantage of the present disclosure is that the system communicates with and charges an energy storage device. Still a further advantage of the present disclosure is that the energy generated from the solar panel can be stored for later use.

Other features and advantages of the present disclosure will be readily appreciated, as the same becomes better understood after reading the subsequent description taken in conjunction with the accompanying drawings.

### BRIEF DESCRIPTION OF THE DRAWINGS

FIG. 1 is a perspective view of a vehicle having a photovoltaic system mounted thereto.

FIG. 2 is a perspective view of another vehicle having a photovoltaic system mounted thereto.

FIG. 3 is a perspective view of a solar panel for the vehicle of FIG. 1 or FIG. 2

FIG. 4 is a top view of the solar roof panel of FIG. 3.

FIG. 5 is an exploded view of the solar panel. of FIG. 3

FIG. 6 is detail view of adjacent solar cells for the solar panel of FIG. 3.

FIG. 7 is a block diagram illustrating a method of electric power distribution using the electrically isolated solar modules.

### DESCRIPTION

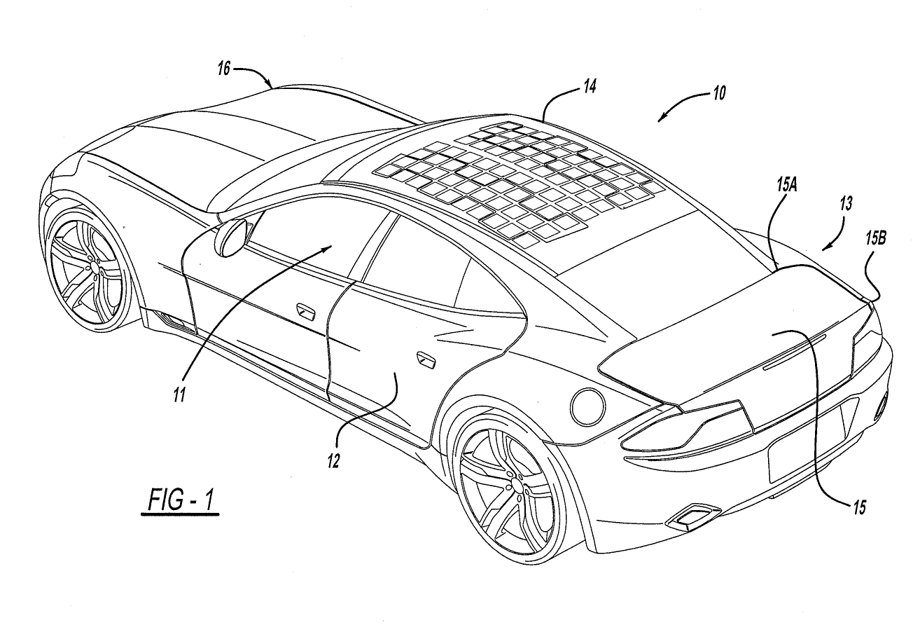

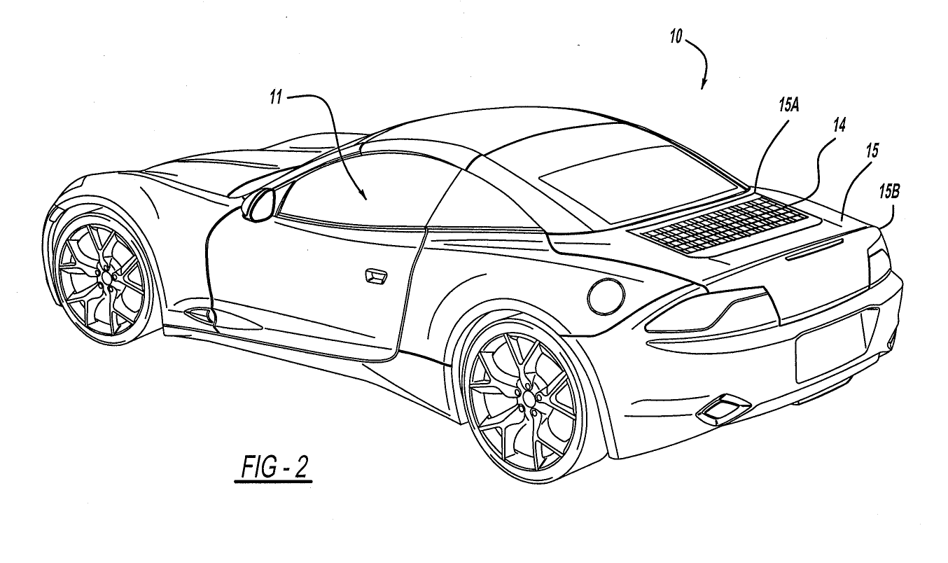

Referring to the FIGS. 1-2, a vehicle 10 having a solar panel 14 is illustrated. In this example the vehicle 10 is a plug-in hybrid vehicle that is both solar and electric powered. The vehicle 10 includes a body structure having a frame and outer panels 12 covering the frame that cooperatively form the shape of the vehicle. The vehicle 10 includes an interior space 11 referred to as a passenger compartment. For a convertible style vehicle 10, the passenger compartment 11 may be enclosed by a moveable convertible top that covers the passenger compartment 11 in an extended position. The vehicle 10 also includes a storage space 13 referred to as a trunk or luggage compartment 13. The trunk or luggage compartment 13 is accessible via a deck lid 15. The deck lid 15 is a panel member pivotally connected to the vehicle body, such that the deck lid 15 can articulate in multiple positions. For example, the deck lid 15 may pivot about a forward edge 15A in order to provide access to the trunk 13 of the vehicle 10, and a rearward edge 15B in order to stow the folded top within the vehicle trunk.

The vehicle 10 also includes a power train that is operable to propel the vehicle 10. In this example, the power train is a plug-in hybrid, and includes an electrically powered motor and motor controller. The vehicle 10 may also include a gasoline powered engine that supplements the electric motor when required under certain operating conditions. The electrical energy can be stored in an energy storage device 70, such as a battery. Various types of batteries 70 are available, such as lead acid, or lithium-ion or the like. It should be appreciated that the vehicle 10 may include more than one type of battery 70 or energy storage device. The battery supplies the power in the form of electricity to operate various vehicle components. In this example, there is a low voltage battery 70 that provides electrical power to vehicle components (e.g., a typical 12 V lead acid battery) and a high voltage battery (e.g. over 60-V traction battery) and in this example a 400 V traction battery that provides electrical power to an electric drive motor. The battery 70 may be in communication with a control system that regulates the distribution of power within the vehicle 10, such as to the electric drive motor, or a vehicle component or other accessories or the like. In this example, the high voltage battery receives electrical energy from a plug-in source and a gasoline engine, and the low voltage battery receives electrical energy from the high voltage battery or a photovoltaic source in a manner to be described. In a further example, the high voltage battery and the low voltage battery can receive electrical energy from a solar source.

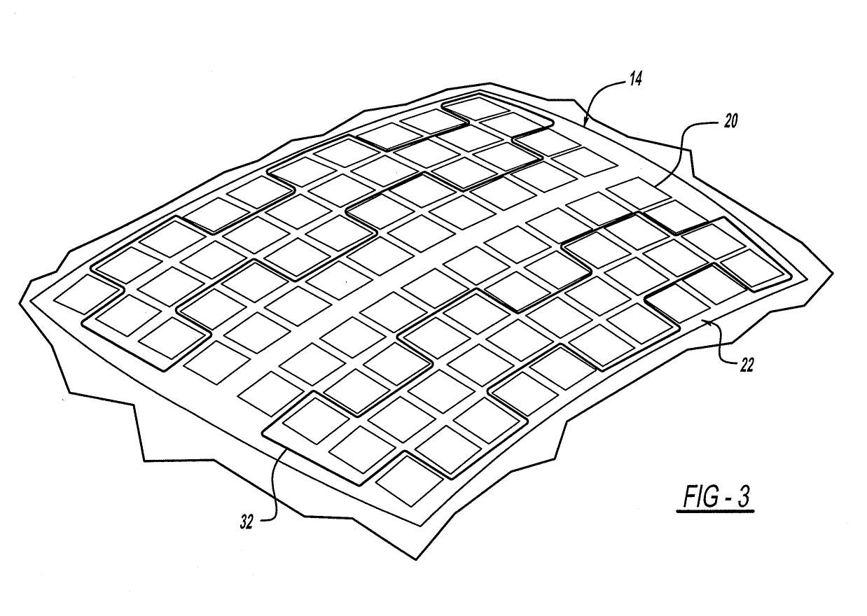

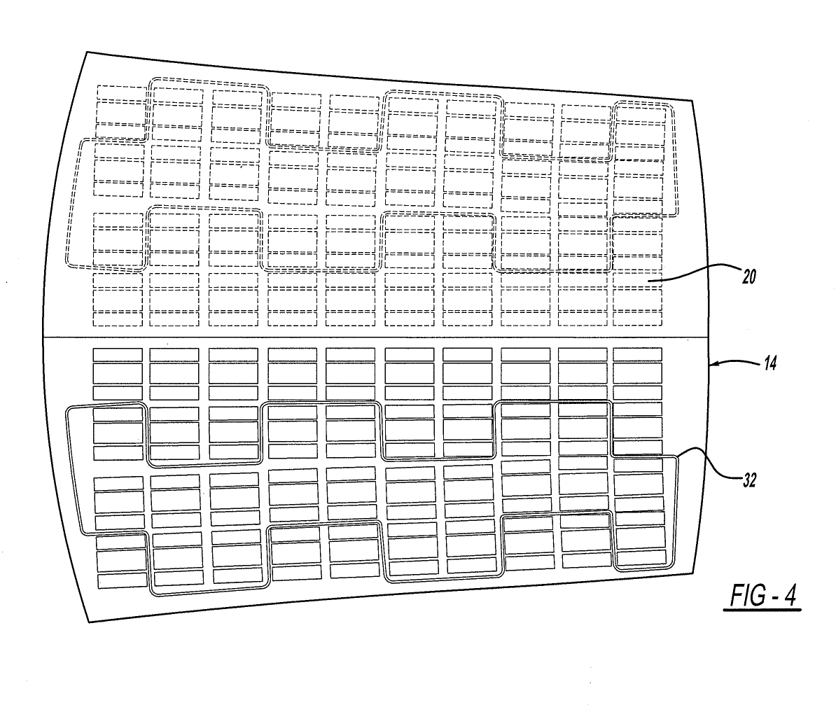

Referring to FIGS. 3-6, the vehicle includes a photovoltaic apparatus 14. that receives light energy and converts that energy to electrical energy. In an example, the photovoltaic apparatus is a generally planar solar panel 14 positioned on a surface of the vehicle 10, so as to receive radiant energy from the sun. The solar panel 14 is positioned to facilitate the collection of radiant energy, such as within a roof panel, deck lid 15 or another vehicle body panel 12. In an example, the solar panel 14 can define a generally planar geometry, a curvilinear geometry or otherwise corresponds to the contours of the vehicle outer panel 12. In a further example, to increase photovoltaic area, retractable solar panels may be provided that are operable to open and expose the solar panels to the sunlight.

The solar panel 14 is operable to collect radiant energy from the sun and convert the sun's energy into stored electrical energy that is available for use in the operation of the vehicle 10. The solar energy is available to supplement that of the other energy sources, such as a plug in source or fossil fuel of this example. The supplemental solar energy effectively increases the performance of the vehicle 10, i.e. increased electric range for use by another vehicle feature or accessory.

The solar panel 14 includes a plurality of solar cells 20 arranged in a solar array as shown in FIGS. 3, 4 and 7. In an example, the individual solar cells 20 may be encapsulated within a polymer layer 18. The solar cells 20 operatively convert absorbed sunlight into electricity. The cells 20 may be grouped and electrically connected and packaged together in a manner to be described. Generally, a solar cell 20 is made from a semiconductor material, such as silicon, silicone crystalline, gallium arsenic (GaAs) or the like. When the solar cell 20 receives the sunlight, a portion of the sunlight is absorbed within the semiconductor, and the absorbed light's energy is transferred to the semiconductor material. The energy from the sunlight frees electrons within the semiconductor material, referred to as free carriers. These free electrons can move to form electrical current, and the resulting free electron flow produces a field causing a voltage. Metal contacts are attached to the cell 20 to allow the current to be drawn off the cell and used elsewhere. The metal contacts may be arranged in a predetermined pattern in a manner to be described.

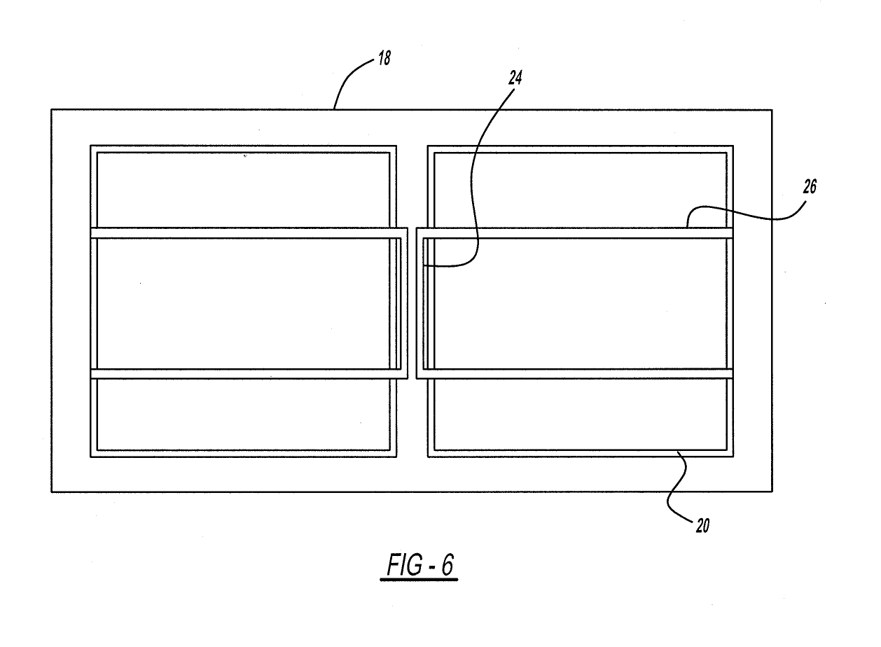

The solar panel 14 is divided into four sections or modules 22 that form electrically separate zones. The solar cells 20 are position within each module in a predetermined arrangement or pattern, such as an array. For example, each module may contains a 5 by 4 array of cells. The modules 22 themselves are connected by cross connector 24, or bus bars as shown in FIG. 6. Further, each cell 20 within a module is electrically connected in series by a cell connector 26 or stringer, as shown in FIG. 6. The dimension of each cell within the module and the corresponding array is sized to fill-up the available space. In a particular example, the array defines a partially and generally splayed pattern.

The solar panel 14 may be fabricated using various techniques, the selection of which is nonlimiting. In an example, the solar panel is fabricated from a glass panel having a laminate structure. In another example, the photovoltaic system can be mounted or incorporated within a composite structure, such as integrally formed within a polymer or composite material. The solar module may be laminated within a durable polymer, such as a scratch resistant polycarbonate. In a further example, the solar modules 22 are mounted in a thin film, such as amorphous silicon or the like. In an even further example, the photovoltaic system includes modules 22 that are formed in other exposed vehicle structures, such as in a window. An organic solar concentrators or specially dyed window may be used that channels light to solar cells at their edges. Accordingly, the solar panel structure will influence characteristics of the vehicle such as weight, cost, packaging or the like.

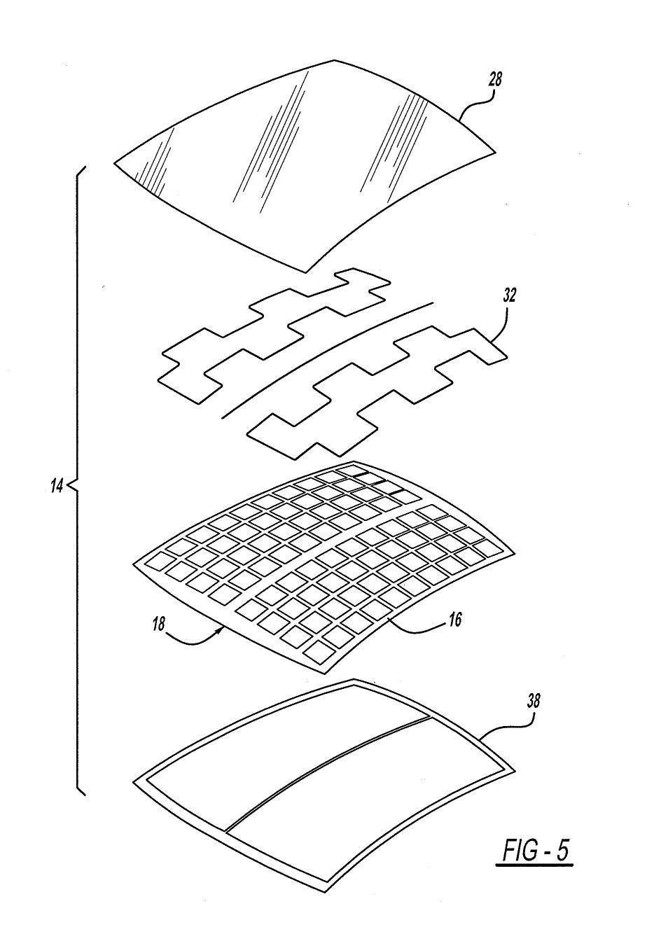

Referring to FIG. 5, an example of a laminate solar panel structure is illustrated. Accordingly, a first layer 16 may be a backing material, such as a foil material. A second layer 18 may be a polymer layer. An example of a polymer material is Ethylene Vinyl Acetate (EVA), or the like. A third layer may be a glass material. The solar cells 20 may be contained within a polymer material. The second layer 18 may include another layer of the polymer coating, thus sandwiching the solar cells 20 and connectors 24 and 26 between the polymer layers. In an example, the solar panel further includes a third or top layer 28 of glass (FIG. 5). This top layer 28 may include various coatings that may be decorative or functional in nature. For example, an inner surface of the top layer 28 can have an antireflective coating since silicon is a shiny material, and photons that are reflected cannot be used by the cell 20. In an example, the antireflective coating reduces the reflection of photons. The antireflective coating can be a black-out screen applied over all areas of the top layer except over the cells 20 that collect solar power. The antireflective coating may be black in color. For example, the black coating may be a material such as an acrylic or frit paint or the like. The top layer 28 may include additional graphic coatings 32 that visually enhance the appearance of the solar panel. In an example, an additional graphic pattern 32 may be applied to the top glass layer, such as by a paint or silk screening process. In a further example, the graphic pattern is in gold paint. The layers may be bonded together by the application of heat to the glass forming the layers together as a single unit.

The solar panel 14 is operatively in communication with a solar charging system 34. To maximize solar energy, and thereby offset fuel usage, the energy generated from the solar panel 14 is stored. Typically, the energy is stored in the low voltage battery 70. Further, the solar charging system 34 may operatively be in communication with a vehicle charging system in a manner to be described. Each of the modules 22 in the solar panel incorporate a maximum power point (MPP) tracking feature that maximizes power output for various solar radiation angles and partial shading conditions of the solar panel 14 in a manner to be described. This feature assumes that if one cell 20 in a particular module 22 is shaded from the sun, then the performance of other cells on the module can also be diminished. Since each module 22 is electrically separate and isolated from the other modules and thus independent, the energy collection operation of the other available modules 22 may be optimized.

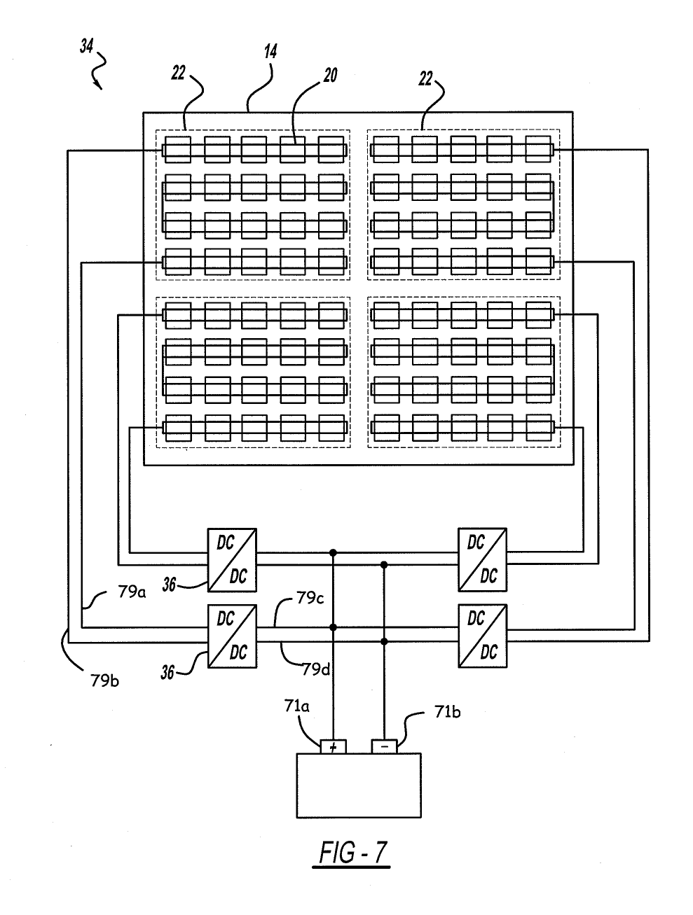

Referring to FIG. 7, the maximum power point tracking feature is described. The solar charging system 34 includes an electrical converter, such as a DC/DC boost converter 36, also referred to as a DC/DC converter, that is in communication with at least one of the solar panel modules 22, to adjust the module 22 output current. For example, each module 22 is coupled to a DC/DC converter 36 to adjust the voltage output from that module 22. The voltage from the modules 22 is lower than that which is needed to charge a low voltage battery 70. In this way, the output voltage of each module 22 is maintained and so the solar energy can be used to charge the low voltage battery 70. In an example, each solar panel module 22 can output up to 3 Amps, i.e. a total of 12 Amps for four modules 22. In this example, the power booster 36 is a DC/DC Energy Booster converter 36 that receives current from the solar module 22 and converts the voltage to a range usable by the vehicle. Typical ranges include 14-16 V for a low voltage battery, or about 216-422 V for a high voltage battery. In this example, there is a DC/DC Energy Booster corresponding to each module. In a further example, the module 22 output voltage is between 10-12 V and the DC/DC converter output is 14-16 V. The low voltage battery 70 is typically a 12 V battery, although the voltage may fluctuate.

Each module 22 includes electrical lines that deliver the voltage to the converter 36. The energy storage device or battery 70 includes a positive terminal 71a and a negative terminal 71b. The voltage from the module 22 is delivered to the converter 36 through a positive voltage input line 79a and a negative voltage input line 79b. The output of the converter 36 includes a positive output voltage line 79c and a negative output voltage line 79d that correspond to positive terminal 71a and negative terminal 71b respectively.

Depending on the available sunlight with respect to the vehicle position, the solar modules 22, or photovoltaic modules, can experience partial or full shading. Shading of a single cell can cause performance of the corresponding module to decrease. For example, a 3% shading can cause a 25% reduction in power. To minimize partial shading losses, each module 22 is electrically isolated from the others. Each module 22 includes its own maximum power point (MPP) tracking. MPP is the point on the current-voltage (I-V) curve of a solar module 22 under illumination, where the product of current and voltage is maximum (Pₘₐₓ, measured in watts). The points on the I and V scales which describe this curve point are named Iₘₚ (current at maximum power) and Vₘₚ (voltage at maximum power).

If the solar panel has a compound curvature (i.e., curving in multiple directions as shown in FIG. 1), one corner of the roof will receive more radiation than another portion at various solar radiation angles. Thus, the cells 20 may be arranged within the module 22 to maximize radiation reception. Since the solar panel 14 is split into a plurality of modules 22, such as four in this example, partial shading conditions affecting only one module may be alleviated. For example, an object laying on the solar cell contained in one module 22 will not affect any other modules 22.

The hybrid vehicle may include other features conventionally known for a vehicle, such as a gasoline motor, other controllers, a drive train or the like.

Many modifications and variations of the present disclosure are possible in light of the above teachings. Therefore, within the scope of the appended claim, the present disclosure may be practiced other than as specifically described.

1.-18. (canceled)

19. A photovoltaic apparatus for a vehicle comprising:
a plurality of solar modules electrically isolated from each other, wherein each solar module of the plurality of solar modules includes a plurality of solar cells for receiving solar radiation and converting the solar radiation to electrical energy, wherein each solar module of the plurality of solar modules is operated at its maximum power point;
a plurality of converters, each electrically coupled to a corresponding solar module of the plurality of the solar modules, to receive the electrical energy from the corresponding solar module and convert the received electrical energy to an output voltage; and
an energy storage device electrically in communication with each of the converters for storing the output voltage.

20. The apparatus of claim 19, wherein the energy storage device is at least one of a low voltage battery, a high voltage battery, and a capacitor.

21. The apparatus of claim 19, wherein the plurality of solar modules are mounted in a solar panel defining a laminate structure having a backing layer, a first polymer layer, a solar module layer, a second polymer layer, and a glass layer.

22. The apparatus of claim 21, wherein the plurality of solar modules are formed within the first and second polymer layers as an integral unit.

23. The apparatus of claim 22, wherein the plurality of solar module is laminated within a durable polymer material.

24. The apparatus of claim 19, wherein each solar module of the plurality of the solar modules is mounted in a solar panel formed of a material comprising at least one of polymer, composite polymer, and thin film amorphous silicon.

25. The apparatus of claim 19, wherein the plurality of solar cells are arranged in a predetermined configuration within each solar module of the plurality of solar modules.

26. The apparatus of claim 25, wherein the predetermined configuration is an array.

27. The apparatus of claim 25, wherein the plurality of solar cells are mounted on cross connectors.

28. The apparatus of claim 19, wherein the plurality of solar modules form a solar panel having four solar modules.

29. The apparatus of claim 19, wherein the plurality of solar modules form a solar panel defining a curvilinear geometry.

30. The apparatus of claim 29, wherein the solar panel curves in multiple directions.

31. The apparatus of claim 19, wherein each solar module of the plurality of solar modules is electrically coupled to a corresponding DC/DC boost converter.

32. The apparatus of claim 19, wherein electrical pathways within each of the plurality of converters is electrically isolated from each other.

33. The apparatus of claim 19, wherein the plurality of solar modules are mounted on a roof of the vehicle.

34. The apparatus of claim 19, wherein the plurality of solar modules is mounted on a deck lid of the vehicle.

35. The apparatus of claim 25, wherein the predetermined configuration maximizes radiation reception by the plurality of solar modules.

36. A method of delivering electrical energy to a vehicle from a photovoltaic apparatus, said method comprising:
collecting solar radiation energy using a plurality of electrically isolated solar modules, wherein each solar module of the plurality of solar modules includes a plurality of solar cells arranged to receive solar radiation and convert the received solar radiation into electrical energy;
operating each solar module of the plurality of solar modules at its maximum power point;
delivering the electrical energy to a plurality of converters, each converter of the plurality of converters corresponding to a solar module of the plurality of solar modules;
boosting the delivered electrical energy with each converter of the plurality of converters; and
outputting the boosted electrical energy from each converter of the plurality of converters to an energy storage device for use by the vehicle.
